(19) United States
(12) Patent Application Publication
(10) Pub. No.: US 2024/0120431 A1
(43) Pub. Date: Apr. 11, 2024

(54) PREPARATION METHOD FOR GROWING GERMANIUM SULFIDE (GeS2) SINGLE-CRYSTAL THIN FILM ON SiO2 SUBSTRATE

(71) Applicant: SOUTH CHINA UNIVERSITY OF TECHNOLOGY, Guangzhou (CN)

(72) Inventors: Guoqiang LI, Guangzhou (CN); Sheng CHEN, Guangzhou (CN); Wenliang WANG, Guangzhou (CN); Jixing CHAI, Guangzhou (CN)

(73) Assignee: SOUTH CHINA UNIVERSITY OF TECHNOLOGY, Guangzhou (CN)

(21) Appl. No.: 18/276,887

(22) PCT Filed: Dec. 30, 2021
(86) PCT No.: PCT/CN2021/143380

§ 371 Date: Aug. 11, 2023

(30) Foreign Application Priority Data
Sep. 30, 2021 (CN) 202111157718.8

(51) Int. Cl. H01L 31/18; C30B 25/04; C30B 25/18; C30B 29/46; H01L 31/032

(52) U.S. Cl. CPC H01L 31/18; C30B 25/04; C30B 25/186; C30B 29/46; H01L 31/0324

(57) ABSTRACT

Clean version of the Abstract A preparation method for growing a germanium sulfide (GeS₂) single-crystal thin film on a SiO₂ substrate includes: cleaning a surface of a substrate with acetone, ethanol and deionized water, where the substrate is a Si/SiO₂ substrate or a SiO₂ glass substrate; photoetching the substrate, spin-coating a photoresist, and performing photoetching and dry etching or wet etching to obtain a groove pattern; depositing a germanium (Ge)-crystal layer in the groove pattern of the substrate to obtain a treated substrate; and putting the treated substrate into a chemical vapor deposition (CVD) device for growth, a growth source being high-purity sulfur (S) powder and high-purity Ge powder, thereby obtaining a GeS₂ single-crystal thin film on the SiO₂ substrate. The preparation method can grow GeS₂ single crystals on the SiO₂ substrate. The GeS₂ single crystals have a high crystalline quality and a small surface roughness.

### CROSS REFERENCE TO THE RELATED APPLICATIONS

This application is the national phase entry of International Application No. PCT/CN2021/143380, filed on Dec. 30, 2021, which is based upon and claims priority to Chinese Patent Application No. 202111157718.8, filed on Sep. 30, 2021, the entire contents of which are incorporated herein by reference.

### TECHNICAL FIELD

The present disclosure relates to the technical field of growth of wide-band-gap semiconductor materials for photoelectric detection, and in particular, to a preparation method for growing a germanium sulfide (GeS₂) single-crystal thin film on a SiO₂ substrate.

### BACKGROUND

GeS₂ is a wide-band-gap and layered in-plane anisotropic group-IV chalcogenide semiconductor. In the monoclinic structure of GeS₂, the layered molecules each are composed of tetrahedral basic units, and all layers are bonded by a Van der Waals (VDW) force. For the unique in-plane anisotropic structure, GeS₂ shows photoelectric anisotropy and electrically-induced phase transition, and has been widely applied to polarized light detectors, memristors, optical memories, and high-specific-energy batteries. At present, GeS₂ crystals are commonly grown by chemical vapor transport (CVT). Specifically, high-purity sulfur (S) powder and high-purity germanium (Ge) powder are molten and sealed in a quartz tube according to a certain proportion, and grown for 24 h at 1,000° C. to obtain GeS₂ bulk crystals. This method requires long growth time and obtains large bulk crystals, which are not easily processed to prepare devices.

In order to better apply GeS₂ to the devices, and realize monolithic integration with a silicon (Si)-based device, a simple method for growing the GeS₂ on a Si-based substrate is desired.

### SUMMARY

The present disclosure provides a preparation method for growing a GeS₂ single-crystal thin film on a SiO₂ substrate, to solve the shortages of the prior art. The preparation method can grow GeS₂ single crystals on the SiO₂ substrate. The prepared GeS₂ single crystals have a high crystalline quality, a small surface roughness, and a corresponding band gap for blue-violet light in a visible light band.

The objective of the present disclosure may be achieved through the following technical solutions:

A preparation method for growing a GeS₂ single-crystal thin film on a SiO₂ substrate includes:

cleaning a surface of a substrate with acetone, ethanol and deionized water, where the substrate is a Si/SiO₂ substrate or a SiO₂ glass substrate;

photoetching the substrate, spin-coating a photoresist, and performing photoetching and dry etching or wet etching to obtain a groove pattern;

depositing a Ge-crystal layer in the groove pattern of the substrate to obtain a treated substrate; and

putting the treated substrate into a chemical vapor deposition (CVD) device for growth, a growth source being high-purity S powder and high-purity Ge powder, thereby obtaining a GeS₂ single-crystal thin film on the SiO₂ substrate.

Further, the wet etching includes a buffered oxide etch (BOE) solution or a piranha solution, and the dry etching includes an inductive coupled plasma (ICP) emission spectrometer.

Further, the step of depositing the Ge-crystal layer in the groove pattern of the substrate is implemented by any one of electronic beam evaporation, pulsed laser deposition (PLD), physical sputtering in physical vapor deposition (PVD), the PVD and CVD.

Further, the Si/SiO₂ substrate has a p-(100) crystal orientation, and a thickness of 300 nm.

Further, the groove pattern is a circular-hole pattern array.

Further, the high-purity S powder has a purity of 99.999%, and the high-purity Ge powder has a purity of 99.999%.

Further, the step of putting the treated substrate into the CVD device for growth, the growth source being the high-purity S powder and the high-purity Ge powder, thereby obtaining the GeS₂ single-crystal thin film on the SiO₂ substrate specifically includes:

putting the treated substrate into the CVD device for the growth;

inverting the treated substrate onto a quartz holder, where an alumina crucible with the Ge powder is provided under the treated substrate;

providing a crucible with the S powder at an upstream of a gas path; and

obtaining the GeS₂ single-crystal thin film on the SiO₂ substrate after certain growth time.

Further, an atmosphere of S vapor or hydrogen sulfide gas is used in the growth.

Further, a region for the alumina crucible with the Ge powder has a growth temperature of 800° C., and a heating rate of 15° C./min.

Further, the crucible with the S powder is 8 cm away from the treated substrate, and a region for the crucible with the S powder has a temperature of 200° C., and a heating rate of 5° C./min.

Compared with the prior art, the present disclosure has the following beneficial effects:
1. The preparation method provided by the present disclosure can directly grow the GeS₂ single-crystal thin film on the substrate. This is beneficial for monolithic integration with a Si-based device.
2. With a plasma-enhanced CVD (PE-CVD) device, the present disclosure can prepare dozens of GeS₂ single-crystal thin films on the SiO₂ substrate at a time. Moreover, the PE-CVD device promotes low-temperature cracking of the source, and can reduce a growth temperature of the GeS₂ single-crystal thin film.

### BRIEF DESCRIPTION OF THE DRAWINGS

To describe the technical solutions in the embodiments of the present disclosure or in the prior art more clearly, the following briefly describes the drawings required for describing the embodiments or the prior art. Apparently, the drawings in the following description show some embodiments of the present disclosure, and those of ordinary skill in the art may still derive other drawings from these drawings without creative efforts.

FIG. 1 is a cross-sectional view after a pattern is etched on a Si/SiO₂ substrate according to an embodiment of the present disclosure;

FIG. 2 is a cross-sectional view when a Ge-crystal layer is evaporated on a patterned substrate according to an embodiment of the present disclosure;

FIG. 3 is a schematic view illustrating growth of a substrate in a PE-CVD device according to an embodiment of the present disclosure;

FIG. 4 is a cross-sectional view of a GeS₂ single-crystal thin film grown on a SiO₂ substrate according to an embodiment of the present disclosure;

FIG. 5 illustrates an X-ray diffraction (XRD) pattern of a GeS₂ single-crystal thin film according to an embodiment of the present disclosure; and

FIG. 6 illustrates a photoluminescence (PL) spectrum of a GeS₂ single-crystal thin film according to an embodiment of the present disclosure.

In the figures: 01-Si substrate layer, 02-Si₂ substrate layer, 03-patterned substrate, 04-Ge-crystal seed layer, 05-PE-CVD device, and 06-GeS₂ single-crystal layer.

### DETAILED DESCRIPTION OF THE EMBODIMENTS

To make objectives, technical solutions and advantages in the embodiments of the present disclosure clearer, the technical solutions in the embodiments of the present disclosure are clearly and completely described below with reference to the accompanying drawings in the embodiments of the present disclosure. Apparently, the described embodiments are merely a part rather than all of the embodiments of the present disclosure. All other embodiments derived from the embodiments in the present disclosure by a person of ordinary skill in the art without creative efforts should fall within the protection scope of the present disclosure. It should be understood that the specific embodiments described herein are merely used to explain the present disclosure, rather than to limit the present disclosure.

### EMBODIMENT

The embodiment provides a preparation method for growing a GeS₂ single-crystal thin film on a SiO₂ substrate. The present disclosure can obtain the high-quality GeS₂ single-crystal thin film with a thickness of about 1 μm on the amorphous substrate. The prepared single-crystal thin film has a good crystalline quality and a flat surface, with a roughness only being a few tenths of a nanometer. Through test with PL spectroscopy, two luminous peaks are provided at wavelengths of 410 nm and 445 nm in a blue-violet band. This indicates that the single-crystal thin film is potential for application in visible light detection.

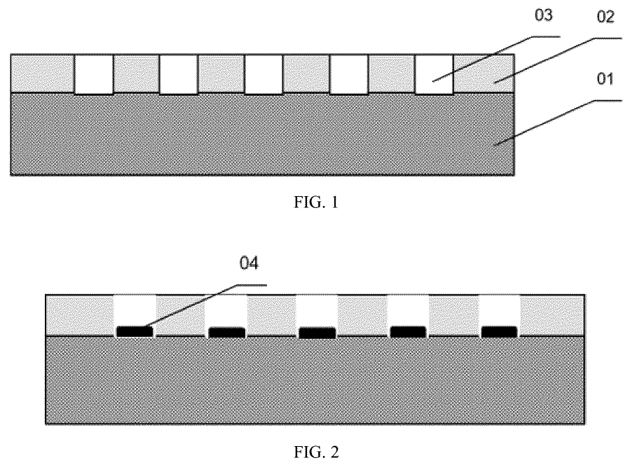

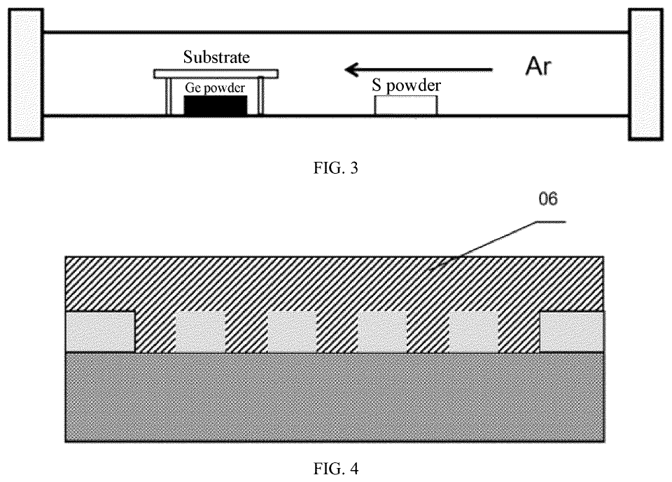

The preparation method for growing a GeS₂ single-crystal thin film on a SiO₂ substrate provided by the embodiment includes the following steps:
(1) Preferably, a Si/SiO₂ substrate with a p-(100) crystal orientation, and a thickness of 300 nm is selected.
(2) A surface of the substrate is cleaned with acetone, ethanol and deionized water.
(3) As shown in FIG. 1, preferably, the substrate is photoetched, spin-coated with a photoresist, and subjected to exposure and development. The substrate is etched with a circular-hole pattern array having a diameter of 50 μm, dried for 90 s at 110° C., and hardened.
(4) Preferably, a SiO₂ layer is etched with an ICP emission spectrometer for 25 s at 10 nm/s, until the Si substrate.
(5) As shown in FIG. 2, preferably, Ge single-crystal particles are evaporated by electron beam evaporation. A 20-nm Ge-crystal layer is evaporated on the etched substrate, and then the surface photoresist is cleaned.
(6) As shown in FIG. 3, preferably, the substrate is put into a PE-CVD device for growth. High-purity S powder (99.999%) and high-purity Ge powder (99.999%) are taken as a growth source. The substrate is inverted onto a quartz holder. An alumina crucible with the Ge powder is provided under the substrate. A region for the alumina crucible with the Ge powder has a growth temperature of 800° C., and a heating rate of 15° C./min. A crucible with the S powder is provided at an upstream of a gas path, and is 8 cm away from the substrate. A region for the crucible with the S powder has a temperature of 200° C., and a heating rate of 5° C./min. An atmosphere of S vapor or hydrogen sulfide gas is used in the growth. Argon (Ar) is used as a transmission gas. With heat preservation, the growth is performed for 1 h at one atmospheric pressure and at 800° C.

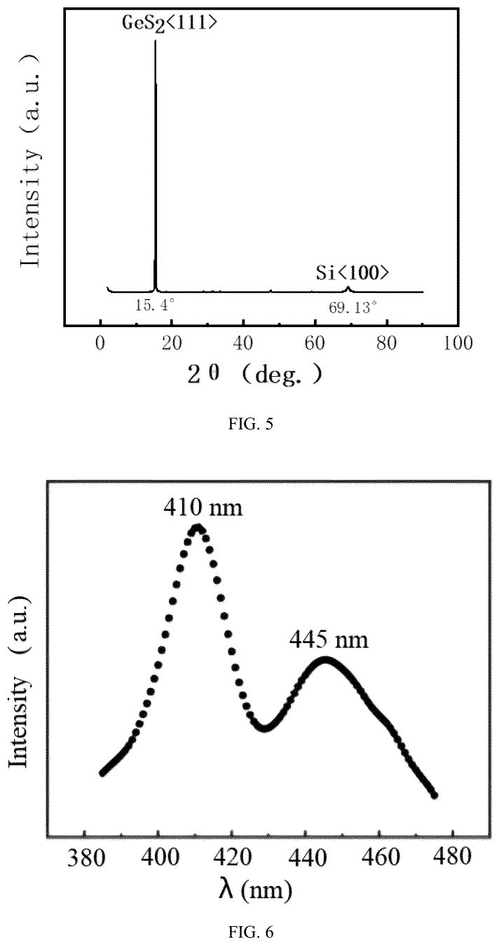

FIG. 4 illustrates a GeS₂ single-crystal thin film grown on a SiO₂ substrate. FIG. 5 illustrates an XRD pattern of a GeS₂ single-crystal thin film. FIG. 6 illustrates a PL spectrum of a GeS₂ single-crystal thin film. As can be seen, the prepared GeS₂ single-crystal thin film has a good crystalline quality and a flat surface, with a roughness only being a few tenths of a nanometer. Through test with PL spectroscopy, two luminous peaks are provided at wavelengths of 410 nm and 445 nm in a blue-violet band. This indicates that the single-crystal thin film is potential for application in visible light detection.

To sum up, the preparation method provided by the present disclosure includes steps of preprocessing the substrate, evaporating the Ge-crystal layer on the substrate to serve as a nucleating layer, and performing high-temperature sulfuration in the CVD device. The method can prepare the GeS₂ single crystal on insulator (SCOI) similar to strained silicon/germanium on insulator (SOUGOI), and can obtain the high-quality GeS₂ single-crystal thin film with a thickness of about 1 μm on the amorphous substrate. The prepared GeS₂ single-crystal thin film has a good crystalline quality and a flat surface, with a roughness only being a few tenths of a nanometer. Through test with PL spectroscopy, two luminous peaks are provided at wavelengths of 410 nm and 445 nm in a blue-violet band. This indicates that the single-crystal thin film is potential for application in visible light detection.

The above described are merely preferred embodiments of the present disclosure, and the protection scope of the present disclosure is not limited thereto. Any equivalent substitutions or changes made by those skilled in the art according to the technical solutions and concepts of the present disclosure within the technical scope of the present disclosure should fall within the protection scope of the present disclosure.

What is claimed is:

1. A preparation method for growing a germanium sulfide (GeS₂) single-crystal thin film on a SiO₂ substrate, comprising:
cleaning a surface of a substrate with acetone, ethanol and deionized water, wherein the substrate is a Si/SiO₂ substrate or a SiO₂ glass substrate;
photoetching the substrate, spin-coating a photoresist, and performing photoetching and dry etching or wet etching to obtain a groove pattern;
depositing a germanium (Ge)-crystal layer in the groove pattern of the substrate to obtain a treated substrate; and
putting the treated substrate into a chemical vapor deposition (CVD) device for growth, a growth source being high-purity sulfur (S) powder and high-purity Ge powder, thereby obtaining the GeS₂ single-crystal thin film on the SiO₂ substrate.

2. The preparation method according to claim 1, wherein the wet etching comprises a buffered oxide etch (BOE) solution or a piranha solution, and the dry etching comprises an inductive coupled plasma (ICP) emission spectrometer.

3. The preparation method according to claim 1, wherein the step of depositing the Ge-crystal layer in the groove pattern of the substrate is implemented by any one of electronic beam evaporation, pulsed laser deposition (PLD), physical sputtering in physical vapor deposition (PVD), the PVD and CVD.

4. The preparation method according to claim 1, wherein the Si/SiO₂ substrate has a p-(100) crystal orientation, and a thickness of 300 nm.

5. The preparation method according to claim 1, wherein the groove pattern is a circular-hole pattern array.

6. The preparation method according to claim 1, wherein the high-purity S powder has a purity of 99.999%, and the high-purity Ge powder has a purity of 99.999%.

7. The preparation method according to claim 1, wherein the step of putting the treated substrate into the CVD device for growth, the growth source being the high-purity S powder and the high-purity Ge powder, thereby obtaining the GeS₂ single-crystal thin film on the SiO₂ substrate comprises:
putting the treated substrate into the CVD device for the growth;
inverting the treated substrate onto a quartz holder, wherein an alumina crucible with the high-purity Ge powder is provided under the treated substrate;
providing a crucible with the high-purity S powder at an upstream of a gas path; and
obtaining the GeS₂ single-crystal thin film on the SiO₂ substrate after certain growth time.

8. The preparation method according to claim 7, wherein an atmosphere of S vapor or hydrogen sulfide gas is used in the growth.

9. The preparation method according to claim 7, wherein a region for the alumina crucible with the high-purity Ge powder has a growth temperature of 800° C., and a heating rate of 15° C./min.

10. The preparation method according to claim 7, wherein the crucible with the high-purity S powder is 8 cm away from the treated substrate, and a region for the crucible with the high-purity S powder has a temperature of 200° C., and a heating rate of 5° C./min.
